(19) United States
(12) Patent Application Publication
(10) Pub. No.: US 2017/0121548 A1
(43) Pub. Date: May 4, 2017

(54) Inked Electrical Conductor

(71) Applicant: U.S.A. as Represented by the Administrator of the National Aeronautics and Space Administration, Washington, DC (US)

(72) Inventor: Curtis W. Hill, Meridianville, AL (US)

(21) Appl. No.: 14/931,523

(22) Filed: Nov. 3, 2015

(51) Int. Cl. C09D 11/52; H05K 3/12; H05K 1/09

(52) U.S. Cl. CPC C09D 11/52; H05K 1/095; H05K 3/12

(57) ABSTRACT

An inked electrical conductor comprises a mixture of silver powder and ethyl cellulose. The silver powder is in a range of approximately 99.0 weight percent of the mixture to approximately 99.5 weight percent of the mixture. The ethyl cellulose is in a range of approximately 0.5 weight percent of the mixture to approximately 1.0 weight percent of the mixture.

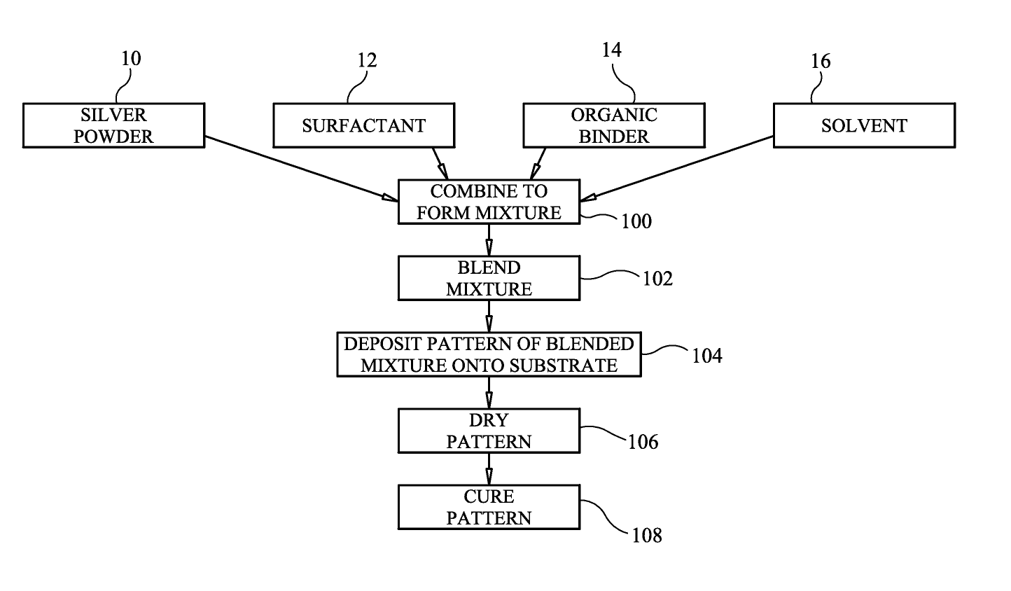

### ORIGIN OF THE INVENTION

The invention described herein was made in the performance of work under a NASA contract, and is subject to the provisions of Public Law 96-517 (35 U.S.C. §202) in which the Contractor has elected not to retain title.

### BACKGROUND OF THE INVENTION

1. Field of the Invention

This invention relates to electrical conductors. More specifically, the invention is an electrical conductor that is printed or inked onto a substrate.

2. Description of the Related Art

Microelectronics products are increasingly being designed, developed, and manufactured using a variety of additive manufacturing and three-dimensional (“3D”) printing processes. The electrical conductors deposited during such processes should not damage existing electronics during deposition, exhibit high-conductivity, exhibit good adhesion with a variety of substrate materials, and exhibit excellent solderability with common solder materials.

### SUMMARY OF THE INVENTION

Accordingly, it is an object of the present invention to provide an inked electrical conductor deposited using conventional manufacturing equipment and processes.

Another object of the present invention is to provide a process for preparing and depositing an electrically conductive ink pattern on a substrate.

Other objects and advantages of the present invention will become more obvious hereinafter in the specification and drawings.

In accordance with an aspect of the present invention, an inked electrical conductor comprises a mixture of silver powder and ethyl cellulose. The silver powder is in a range of approximately 99.0 weight percent of the mixture to approximately 99.5 weight percent of the mixture. The ethyl cellulose is in a range of approximately 0.5 weight percent of the mixture to approximately 1.0 weight percent of the mixture.

In another aspect of the present invention, an electrically conductive ink pattern is prepared and deposited by a new process. The process begins with a mixture of silver powder, a surfactant, an organic binder, and a solvent. The silver powder is in a range of approximately 30 weight percent of the mixture to approximately 90 weight percent of the mixture. The surfactant is up to approximately 5 weight percent of the mixture. The organic binder is up to approximately 15 weight percent of the mixture. The solvent is up to approximately 50 weight percent of the mixture. The mixture is blended to disperse the silver powder in the mixture wherein a dispersed mixture is created. A pattern of the dispersed mixture is deposited onto a substrate. The pattern is dried and then cured.

### BRIEF DESCRIPTION OF THE DRAWING(S)

Other objects, features and advantages of the present invention will become apparent upon reference to the following description of the preferred embodiments and to the drawings, wherein corresponding reference characters indicate corresponding parts throughout the several views of the drawings and wherein:

The sole FIGURE is a flow diagram of a process for preparing and depositing an electrically conductive ink pattern in accordance with an embodiment of the present invention.

### DESCRIPTION OF THE PREFERRED EMBODIMENT(S)

Referring now to the sole FIGURE, a flow diagram illustrates the process steps for preparing and depositing an electrically conductive ink pattern onto a substrate in accordance with an embodiment of the present invention. The resulting inked electrical conduct (or “conductor ink” as it will also be referred to herein) is highly conductive, has exhibited good adhesion to substrate materials, and has exhibited good solderability with conventional eutectic tin-lead solder materials or silver-containing solder materials. Solderability to electronic components is defined as good wetting of the ink and component surfaces and good coverage as defined by, for example, the IPC-610-A test document. As will be explained further below, ingredient amounts and/or processing step variations can be used to tailor the overall process to a particular type of additive manufacturing or 3D printing process.

The four ingredients needed to commence the conductor ink preparation/deposition process include silver powder 10, a surfactant 12 for wetting the ingredients, an organic vehicle or binder 14 for binding the silver powder particles, and a solvent 16 for controlling viscosity of the combined ingredients during processing for a particular deposition process. These four ingredients are combined at process step 100 to form a mixture. Prior to describing the remaining steps of the preparation/deposition process, features of the four ingredients will be described.

In general, silver powder 10 is a fine powder whose particle sizes range from approximately 10 nanometers to approximately 300 nanometers. For best electrical conductivity, silver powder 10 should have a purity of greater than approximately 99.5%. However, it is to be understood that lower percentages of silver purity may be acceptable for some applications and, therefore, could be used without departing from the scope of the present invention. The amount of silver powder 10 combined into the mixture at process step 100 is between approximately 30 weight percent of the mixture and approximately 90 weight percent of the mixture.

Surfactant 12 serves to wet the ingredients thereby enhancing the mixture's ingredient dispersal and flow characteristics throughout the process. A variety of conventional surfactants can be used such as phosphate ester surfactants and polyvinylpyrrolidone surfactants. The amount of surfactant 12 included in the mixture created at process step 100 can be up to approximately 5 weight percent of the mixture. Surfactant 12 is a processing ingredient that does not remain in the ultimate inked electrical conductor.

Organic binder 14 serves to bind the silver powder particles thereby allowing the particles to be retained during processing and in the ultimate inked electrical conductor. A variety of organic binders, such as ethyl cellulose, can be used. The amount of organic binder 14 included in the mixture created at process step 100 can be up to approximately 15 weight percent of the mixture. The viscosity of the organic binder 14 can be selected depending on the deposition process that is to be used. Organic binder 14 is both a processing ingredient and one that (at least in portion) remains in the ultimate inked electrical conductor.

Solvent 16 serves to control the viscosity of the mixture created at process step 100 and during the remaining processing steps. A variety of solvents can be used such as acetone, butyl carbitol, texanol ether, terpineol, and mixtures thereof. The amount of solvent 16 included in the mixture created at process step 100 can be up to approximately 50 weight percent of the mixture. Solvent 16 is a processing ingredient that does not remain in the ultimate inked electrical conductor.

Referring again to the FIGURE, the mixture created at processing step 100 is next blended at process step 102 in order to disperse the silver powder particles throughout the mixture. The type of blending process and apparatus used depends on the viscosity of the mixture created in process step 100. For example, for more viscous mixtures created for screen printing and 3D printing deposition applications, process step 102 can be carried out using mill rolling processes/apparatus to disperse the silver powder particles uniformly. For mixtures that must be less viscous in order to support (for example) aerosol spray deposition, process step 102 can be carried out in a shear mixing process/apparatus to disperse the silver powder particles uniformly. Since the viscosity of the silver-powder-dispersed or blended mixture created by process step 102 can vary depending on the deposition process that is to be used, the viscosity of the blended mixture can be in a range of approximately 20 centipoise to approximately 30,000 centipoise without departing from the scope of the present invention.

The blended mixture from process step 102 is then deposited onto a substrate of choice in process step 104. In general, the blended mixture is deposited in the form of a pattern on a substrate where the pattern defines one or more electrically conductive paths on the substrate. Deposition process step 104 can be carried out by one of a screen printing process, a 3D printing process, or an aerosol spray deposition process without departing from the scope of the present invention.

The substrate with the deposited pattern is subjected to a drying process step 106 that commences evaporation of surfactant 12 and solvent 14 from the deposited pattern. For the formulation ranges described herein, the temperature for drying to occur need only be in a range of approximately 50° to approximately 100° C. Such low-temperature drying will have no negative impact on typical substrate materials or electronics devices that are present during the drying process. The time for such drying to occur is generally in a range of approximately 10 minutes to approximately 30 minutes.

The substrate with the dried pattern is next subjected to a curing process step 108 that cures the dried pattern to complete the evaporation of processing ingredients as well as cause the pattern to adhere to the substrate thereby forming the ultimate inked electrical conductor or conductor ink. For the formulation ranges described herein, the temperature for curing to occur need only be in a range of approximately 140° C. to approximately 240° C. Such low-temperature curing will have no negative impact on typical substrate materials or electronics devices that are present during the curing process. The time for curing of the pattern is generally in a range of approximately 60 minutes to approximately 120 minutes.

As a result of the above-described process, an inked electrical conductor has a formulation comprised of approximately 99.0-99.5 weight percent of silver powder and approximately 0.5-1.0 weight percent of the organic binder, e.g., ethyl cellulose. Two examples of an inked electrical conductor prepared and deposited in accordance with the present invention will be described below. In each example, the substrate used for depositing a pattern thereon was an alumina ceramic substrate.

### Example 1

### Aerosol Spray Deposited Conductor Ink

In this example, the four ingredients provided at process step 100 consisted of the following:
40 weight percent silver powder having nominal particle sizes of 20 nanometers,
5 weight percent of a polyvinylpyrrlidone surfactant (e.g., Ganex V-216 available from Ashland Chemicals, Federalsburg, Md.);
5 weight percent organic binder (e.g., N4 ethyl cellulose binder available from Ashland Chemicals); and
50 weight percent solvent (e.g., acetone).

The above combination was blended in a high shear mixer at speeds ranging from 3000-5000 rpm in order to disperse the silver powder particles uniformly. The viscosity of this blended mixture was approximately 45 centipoise. The blended mixture was deposited as a pattern on the alumina ceramic substrate via aerosol spray deposition. In the example, the blended mixture was sprayed onto the substrate using a model L5M-A shear mixer available from Silverson Machines Inc., Longmeadow, Mass. The resulting pattern was dried at a temperature of 70° C. for 15 minutes. The pattern was then cured at a temperature of 180° C. for 60 minutes.

The resulting dried/cured pattern was approximately 0.0004 centimeters thick. Adhesion of the conductor ink pattern to the substrate was determined to be good pursuant to adhesion tape testing protocol specified by the IPC test specification IPC-TM-650. Resistivity of the conductor ink pattern was 0.0000624 Ohms/centimeter, and conductivity of the conductive ink pattern was 8.01×10⁵ Siemens/meter. These results show that the sprayed version of the present invention provides acceptable properties for a commercial conductor ink that will be suitable for high-volume microelectronics production.

### Example 2

### Screen Printed Conductor Ink

In this example, the four ingredients provided at process step 100 consisted of the following:
73.5 weight percent silver powder having nominal particle sizes of 20 nanometers;
1 weight percent of a phosphate ester surfactant (e.g., Dextral OC-40 available from Ashland Chemicals);
1 weight percent organic binder (e.g., N200 ethyl cellulose binder available from Ashland Chemicals); and
24.5 weight percent solvent (e.g., butyl carbitol).

The above viscous combination was blended by milling on a three-roll mill (e.g., as available from Torrey Hill Technologies, San Diego, Calif.) in order to disperse the silver powder particles uniformly. The viscosity of the blended mixture was approximately 13,500 centipoise. The blended mixture was deposited as a pattern on the alumina ceramic substrate via screen printing deposition. The resulting pattern was dried at a temperature of 75° C. for 15 minutes. The pattern was then cured at a temperature of 180° C. for 90 minutes.

The resulting dried/cured pattern was approximately 0.0008 centimeters thick. Adhesion of the conductor ink pattern to the substrate was determined to be good pursuant to adhesion tape testing protocol specified by the IPC test specification IPC-TM-650. Resistivity of the conductor ink pattern was 0.0000312 Ohms/centimeter, and conductivity of the conductor ink pattern was 3.21×10̂6 Siemens/meter. These results show that the screen printed version of the present invention provides acceptable properties for a commercial conductor ink that will be suitable for high-volume microelectronics production.

The advantages of the present invention are numerous. The inked electrical conductor is highly conductive and can be prepared/deposited in ways that allow it to be used in current additive manufacturing processes and 3D printing processes. The conductor ink exhibits good substrate adhesion, conductivity, and solderability. The preparation/deposition process is not harmful to most substrate materials and electronic devices that might be present during deposition.

Although the invention has been described relative to a specific embodiment thereof, there are numerous variations and modifications that will be readily apparent to those skilled in the art in light of the above teachings. It is therefore to be understood that, within the scope of the appended claims, the invention may be practiced other than as specifically described.

What is claimed as new and desired to be secured by Letters Patent of the United States is:

1. An inked electrical conductor comprising a mixture of silver powder and ethyl cellulose, said silver powder being in a range of approximately 99.0 weight percent of said mixture to approximately 99.5 weight percent of said mixture, and said ethyl cellulose being in a range of approximately 0.5 weight percent of said mixture to approximately 1.0 weight percent of said mixture.

2. An inked electrical conductor as in claim 1, wherein said silver powder comprises particles of silver in a range of approximately 10 nanometers to approximately 300 nanometers.

3. An electrically conductive ink pattern prepared and deposited by a process comprising the steps of:
providing a mixture of silver powder, a surfactant, an organic binder, and a solvent, said silver powder being in a range of approximately 30 weight percent of said mixture to approximately 90 weight percent of said mixture, said surfactant being up to approximately 5 weight percent of said mixture, said organic binder being up to approximately 15 weight percent of said mixture, and said solvent being up to approximately 50 weight percent of said mixture;
blending said mixture to disperse said silver powder in said mixture wherein a dispersed mixture is created;
depositing a pattern of said dispersed mixture onto a substrate;
drying said pattern; and
curing said pattern.

4. A process according to claim 3, wherein said silver powder has a purity of greater than approximately 99.5% and comprises particles of silver in a range of approximately 10 nanometers to approximately 300 nanometers.

5. A process according to claim 3, wherein said surfactant is selected from the group consisting of a phosphate ester surfactant and a polyvinylpyrrolidone surfactant.

6. A process according to claim 3, wherein said organic binder comprises ethyl cellulose.

7. A process according to claim 3, wherein said solvent is selected from the group consisting of acetone, butyl carbitol, texanol ether, terpineol, and mixtures thereof.

8. A process according to claim 3, wherein said step of drying occurs at a temperature in a range of approximately 50° C. to approximately 100° C.

9. A process according to claim 8, wherein said step of drying is carried out for approximately 10 minutes to approximately 30 minutes.

10. A process according to claim 3, wherein said step of curing occurs at a temperature in the range of approximately 140° C. to approximately 240° C.

11. A process according to claim 10, wherein said step of curing is carried out for approximately 60 minutes to approximately 120 minutes.

12. A process according to claim 3, wherein said step of blending comprises the step of mill rolling said mixture.

13. A process according to claim 3, wherein said step of blending comprises the step of shear mixing said mixture.

14. A process according to claim 3, wherein a viscosity of said dispersed mixture is in a range of approximately 20 centipoise to approximately 30,000 centipoise.

15. A process according to claim 3, wherein said step of depositing comprises a processing step selected from the group consisting of screen printing, three-dimensional printing, and aerosol spray deposition.

16. An electrically conductive ink pattern prepared and deposited by a process comprising the steps of:
providing a mixture of silver powder, a surfactant, an ethyl cellulose binder, and a solvent, said silver powder having a purity of greater than approximately 99.5%, said silver powder defined by particles of silver in a range of approximately 10 nanometers to approximately 300 nanometers, said silver powder being in a range of approximately 30 weight percent of said mixture to approximately 90 weight percent of said mixture, said surfactant being up to approximately 5 weight percent of said mixture, said ethyl cellulose binder being up to approximately 15 weight percent of said mixture, and said solvent being up to approximately 50 weight percent of said mixture;
blending said mixture to disperse said silver powder in said mixture wherein a dispersed mixture is created;
depositing a pattern of said dispersed mixture onto a substrate;
drying said pattern; and
curing said pattern.

17. A process according to claim 16, wherein said surfactant is selected from the group consisting of a phosphate ester surfactant and a polyvinylpyrrolidone surfactant.

18. A process according to claim 16, wherein said solvent is selected from the group consisting of acetone, butyl carbitol, texanol ether, terpineol, and mixtures thereof.

19. A process according to claim 16, wherein said step of drying occurs at a temperature in a range of approximately 50° C. to approximately 100° C.

20. A process according to claim 19, wherein said step of drying is carried out for approximately 10 minutes to approximately 30 minutes.

21. A process according to claim 16, wherein said step of curing occurs at a temperature in the range of approximately 140° C. to approximately 240° C.

22. A process according to claim 21, wherein said step of curing is carried out for approximately 60 minutes to approximately 120 minutes.

23. A process according to claim 16, wherein said step of blending comprises the step of mill rolling said mixture.

24. A process according to claim 16, wherein said step of blending comprises the step of shear mixing said mixture.

25. A process according to claim 16, wherein a viscosity of said dispersed mixture is in a range of approximately 20 centipoise to approximately 30,000 centipoise.

26. A process according to claim 16, wherein said step of depositing comprises a processing step selected from the group consisting of screen printing, three-dimensional printing, and aerosol spray deposition.
